(19) United States
(12) Patent Application Publication
(10) Pub. No.: US 2014/0359202 A1
(43) Pub. Date: Dec. 4, 2014

(54) READING VOLTAGE CALCULATION IN SOLID-STATE STORAGE DEVICES

(71) Applicant: Western Digital Technologies, Inc., Irvine, CA (US)

(72) Inventors: YONGKE SUN, PLEASANTON, CA (US); DENGTAO ZHAO, SANTA CLARA, CA (US); HAIBO LI, SUNNYVALE, CA (US); KROUM S. STOEV, PLEASANTON, CA (US)

(21) Appl. No.: 13/917,518

(22) Filed: Jun. 13, 2013

Related U.S. Application Data
(60) Provisional application No. 61/829,955, filed on May 31, 2013.

(51) Int. Cl. G11C 16/34; G06F 12/02

(52) U.S. Cl. CPC G11C 16/34; G06F 12/0246
USPC 711/103; 365/185.11

(57) ABSTRACT

An error management system for a data storage device includes adjusted reading voltage level calculation functionality. Adjusted reading voltage level calculation may be based on the generation and use of an index in which data retention characteristics of a drive are used to look-up corresponding reading voltage levels. In certain embodiments, reading voltage level calculation is based at least in part on curve-fitting procedures/algorithms, wherein curves are fitted to bit error rate data points or cumulative memory cell distributions and are solved according to one or more algorithms to determine optimal reading voltage levels.

### CROSS REFERENCE TO RELATED APPLICATIONS

This application claims priority to provisional U.S. Patent Application Ser. No. 61/829,955 (Atty. Docket No. T6268.P), filed on May 31, 2013, which is hereby incorporated by reference in its entirety.

### BACKGROUND

1. Technical Field

This disclosure relates to data storage systems. More particularly, the disclosure relates to systems and methods for calculating reading voltage levels in solid-state data storage devices.

2. Description of the Related Art

Certain solid-state memory devices, such as flash drives, store information in an array of memory cells constructed with floating gate transistors. In single-level cell (SLC) flash devices, each cell stores a single bit of information. In multi-level cell (MLC) devices, each cell stores two or more bits of information. When a read operation is performed, the electrical charge levels of the cells are compared to one or more voltage reference values (also called “reading voltage level” or “voltage threshold”) to determine the state of individual cells. In SLC devices, a cell can be read using a single voltage reference value. In MLC devices, a cell is read using multiple voltage references values. Certain solid-state devices allow for a memory controller to set reading voltage levels.

Various factors can contribute to data read errors in solid-state memory devices. These factors include charge loss or leakage over time, and device wear caused by usage. When the number of bit errors on a read operation exceeds the ECC (error correction code) correction capability of the storage subsystem, the read operation fails. Reading voltage levels can contribute to a device's ability to decode data.

### BRIEF DESCRIPTION OF THE DRAWINGS

Various embodiments are depicted in the accompanying drawings for illustrative purposes, and should in no way be interpreted as limiting the scope of the inventions. In addition, various features of different disclosed embodiments can be combined to form additional embodiments, which are part of this disclosure. Throughout the drawings, reference numbers may be reused to indicate correspondence between reference elements.

FIG. 1 is a block diagram illustrating an embodiment of a solid-state storage device including an error management module.

FIG. 2 is a graph showing a probability distribution of cells in a non-volatile solid-state memory array according to an embodiment.

FIG. 3 is a graph showing state cross point shift of a probability distribution according to an embodiment.

FIG. 4 is a graph showing bit error rate versus time relationship data in an example solid-state storage device.

FIG. 5 is a flowchart illustrating a process for calculating reading voltage level values according to an embodiment.

FIG. 6A is a flow diagram illustrating an embodiment of a process for generating a data retention index.

FIG. 6B is a flow diagram illustrating an embodiment of a process for utilizing a data retention index.

FIG. 7 is a graph showing reading voltage level shift versus bit error count relationship data in an embodiment.

FIG. 8 is a graph showing reading voltage level shift data in an embodiment.

FIGS. 9-10 show graphical bit error count data in one or more embodiments.

FIG. 11 is a graph showing bit error count data in an embodiment.

FIG. 12A is a table including bit error count data according to an embodiment.

FIG. 12B is a graph showing bit error count data in an embodiment.

FIG. 13 is a flow diagram illustrating an embodiment of a process for calculating reading voltage levels using polynomial fitting.

FIG. 14 is a graph showing cumulative state distribution information in an embodiment.

FIG. 15 is a graph showing cumulative state distribution information in an embodiment.

FIG. 16 is a flow diagram illustrating an embodiment of a process for calculating reading voltage levels using polynomial fitting.

### DETAILED DESCRIPTION

While certain embodiments are described, these embodiments are presented by way of example only, and are not intended to limit the scope of protection. Indeed, the novel methods and systems described herein may be embodied in a variety of other forms. Furthermore, various omissions, substitutions and changes in the form of the methods and systems described herein may be made without departing from the scope of protection.

### Overview

Data storage cells in solid-state memory, such as multi-level-per-cell (MLC) flash memory, may have distinct threshold voltage distribution (Vₜ) levels, corresponding to different memory states. For example, in an MLC implementation, different memory states in solid-state memory may correspond to a distribution of voltage levels ranging between reading voltage (VR) levels; when the charge of a memory cell falls within a particular range, one or more reads of the page may reveal the corresponding memory state of the cell. The term “read” is used herein with respect to voltage reads of solid-state memory according to its broad and ordinary meaning, and may refer to read operations on a page, including a plurality of cells (e.g., thousands of cells), or may be used with respect to a voltage charge level of a single memory cell.

Reading voltage levels can advantageously be set to values in the margins between memory states. According to their charge level, memory cells store different binary data representing user data. For example, based on its charge level, each cell generally falls into one of the memory states, represented by associated data bits.

Over time, and as a result of various physical conditions and wear from repeated program/erase (P/E) cycles, the margins between the various distribution levels may be reduced, so that voltage distributions overlap to some extent. Such reduction in read margin may be due to a number of factors, such as loss of charge due to flash cell oxide degradation, over-programming caused by erratic program steps, programming of adjacent erased cells due to heavy reads or writes in the locality of the cell (or write disturbs), and/or other factors, all of which may contribute to read failure in a solid-state storage device.

In addition to data corruption, read failure can result from the use of fixed reading voltage levels that are not adapted to the voltage distribution shifts of the memory cells inside the device. Although devices may be programmed with fixed manufacturer-determined reading voltage levels, certain embodiments may provide for overriding of such default manufacturer read levels. Certain embodiments disclosed herein provide systems and methods for reading memory cells at adjusted/optimized reading voltage levels, which may provide for improved data recovery. In particular, three techniques for determining adjusted/optimal read voltage levels are described below, which may be applicable to either generic or pre-calibrated solid-state memories.

### Terminology

“Page,” or “E-page,” as used herein may refer to the unit of data correction of embodiments disclosed herein. For example, error correction/calibration operations may be performed on a page-by-page basis. A page of data may be any suitable size. For example, a page may comprise 1 k, 2 k, 4 k, or more bytes of data. Furthermore, the term “location,” or “memory location” is used herein according to its broad and ordinary meaning and may refer to any suitable partition of memory cells within one or more data storage devices. A memory location may comprise a contiguous array of memory cells or addresses (e.g., a page).

As used in this application, “non-volatile solid-state memory” may refer to solid-state memory such as NAND flash. However, the systems and methods of this disclosure may also be useful in more conventional hard drives and hybrid drives including both solid-state and hard drive components. Solid-state memory may comprise a wide variety of technologies, such as flash integrated circuits, Phase Change Memory (PC-RAM or PRAM), Programmable Metallization Cell RAM (PMC-RAM or PMCm), Ovonic Unified Memory (OUM), Resistance RAM (RRAM), NAND memory, NOR memory, EEPROM, Ferroelectric Memory (FeRAM), MRAM, or other discrete NVM (non-volatile solid-state memory) chips. The non-volatile solid-state memory arrays or storage devices may be physically divided into planes, blocks, pages, and sectors, as is known in the art. Other forms of storage (e.g., battery backed-up volatile DRAM or SRAM devices, magnetic disk drives, etc.) may additionally or alternatively be used.

### Data Storage System

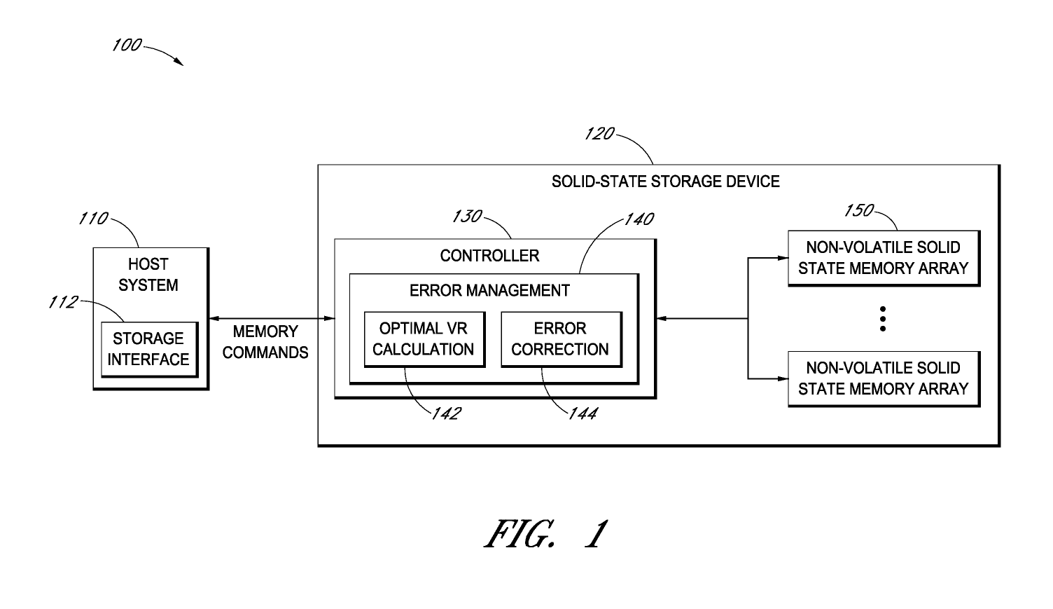

FIG. 1 is a block diagram illustrating an embodiment of a solid-state storage device 120 incorporating error management functionality. As shown, the solid-state storage device 120 (e.g., hybrid hard drive, solid-state drive, any storage device utilizing solid-state memory, etc.) includes a controller 130, which in turn includes an error management module 140. In certain embodiments, the error management module 140 is configured to detect and correct certain kinds of internal data corruption of one or more non-volatile solid-state memory arrays 150, which may comprise one or more blocks of storage, each comprising a plurality of flash pages. The controller 130 can further include internal memory (not shown), which may be of one or more suitable memory types. In some embodiments, the controller 130 is configured to perform the reading voltage level adjustment functions as further described below.

The error management module 140 includes an error correction module 144 for encoding and decoding data transferred to/from the non-volatile memory array(s) 150. Furthermore, the error management module 140 includes an optimal VR calculation module 142 for calculating adjusted/optimal reading voltage levels in order to provide optimal data to the error correction module 144 according to one or more embodiments disclosed herein to increase the error correction module's ability to decode data stored in the memory array(s).

In certain embodiments, the controller 130 is configured to receive memory access commands from a storage interface (e.g., a device driver) 112 residing on a host system 110. The controller 130 is configured to execute commands in response to such host-issued memory commands in the non-volatile solid-state memory arrays 150. Storage access commands communicated by the storage interface 112 can include write and read commands issued by the host system 110. The commands can specify a block address in the solid-state storage device 120, and the controller 130 can execute the received commands in the non-volatile solid-state memory array 150. Data may be accessed/transferred based on such commands. In an embodiment, the solid-state storage device 120 may be a hybrid disk drive that additionally includes magnetic memory storage (not shown). In such case, one or more controllers 130 may control the magnetic memory storage and the non-volatile solid-state memory array(s) 150.

The solid-state storage device 120 can store data received from the host system 110 so that the solid-state storage device 120 can act as memory storage for the host system 110. To facilitate this function, the controller 130 can implement a logical interface. The logical interface can present to the host system 110 storage system memory as a set of logical addresses (e.g., contiguous address) where data can be stored. Internally, the controller 130 can map logical addresses to various physical memory addresses in the non-volatile solid-state memory array 150 and/or other memory module(s).

### Memory Cell Distribution in Solid-State Memory

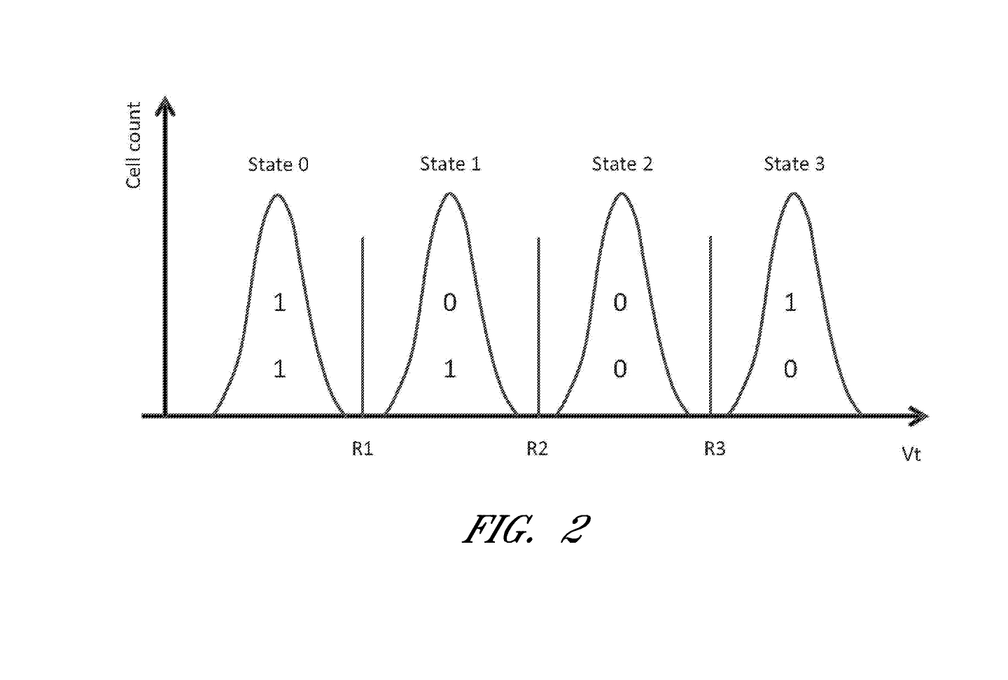

FIG. 2 is a graph showing a probability distribution of cells in a non-volatile solid-state memory array according to an embodiment. Flash memory, such as multi-level cell (MLC) NAND flash memory, may store two or more bits of information per cell. While certain embodiments disclosed herein are described in the context of MLCs, it should be understood that the concepts disclosed herein may be compatible with single level cell (SLC), three-level cell (TLC) technology (a type of MLC NAND), and/or other types of technology. Data is generally stored in MLC NAND flash memory in binary format. For example, two-bit-per-cell memory cells can have 4 distinct programming voltage levels, and 3-bit-per-cell memory cells can have 8 distinct programming voltage levels, and so on. Therefore, individual memory cells can store different binary bits according to the amount of charge stored thereon.

The horizontal axis depicted in FIG. 2 represents cell voltage level. The vertical axis represents the number of cells that have the corresponding voltage values. Thus, the four distribution curves represent the number of cells, broken down by the four distributions, which have the corresponding voltage values. As shown, the voltage distribution of the memory cells may include a plurality of distinct levels, or states (e.g., States 0-3 in this example 2-bit-per cell MLC configuration, as shown). Read reference values (i.e., voltage threshold levels R1-R3) may be placed between these levels. In certain embodiments, reading voltage values R1, R2, and R3 may be preset by a device manufacturer. For example, with respect to a NAND flash device, reading voltage levels R1, R2, and R3 may be pre-calibrated by the NAND manufacturer and stored in the NAND flash chip ROM registers. The NAND manufacturers may optimize these VR's to provide successful readout of the data stored in the NAND based on generally-applicable device characteristics. However, pre-defined, static sets of VR's may not be adequate for the various operational situations, which may include flash memory aging and data retention effects which are often encountered in applications.

The gap between the levels (i.e., margin between programmed states), in which the read voltage references may advantageously be positioned in certain embodiments, is referred to as “read margin.” Over time, and as a result of various physical conditions and wear, for example from being subjected to repeated P/E cycles, the read margins between the various distribution levels may be reduced, resulting in both data retention problems and higher read errors beyond certain limits. Such reduction in read margin may be due to a number of factors, such as loss of charge due to flash cell oxide degradation, over-programming caused by erratic program steps, programming of adjacent erased cells due to heavy reads or writes in the locality of the cell (or write disturbs), and/or other factors. As read margins are diminished, or disappear, fixed read voltage levels such as R1, R2, and R3, may prove less reliable. Therefore, adjustment of one or more reading voltage levels can improve decoding reliability in certain embodiments.

While the diagram of FIG. 2 illustrates a distribution for 2-bit-per-cell flash memories, embodiments and features disclosed herein may be applicable to other types of coding schemes. With respect to the embodiment of FIG. 2, the coding for States 0-3 can be, for example, ‘11,’‘01,’‘00,’ and ‘10,’ or any other coding. Each cell may generally fall into one of the illustrated states and correspondingly represents two bits. For one word line (WL), which can be connected to tens of thousands of cells in a NAND array, the lower digit of the cells may be referred to as the “lower page,” and the upper digit may be referred to as the “upper page.” For 3-bit-per-cell flash memories, there may also be intermediate digits, which may be referred to as “middle pages.” Reading voltage levels and operations are dependent on the coding of these states. For example, for the coding as shown in FIG. 2 for the 2-bit-per-cell flash memories, one read at R2 may be required to read out the lower page, and two reads at both R1 and R3 may be required to read out the upper page. As shown in the distribution of FIG. 2, these reading voltages may be selected between state distributions in the case where the distributions for different states are narrow so that there is no overlap between them.

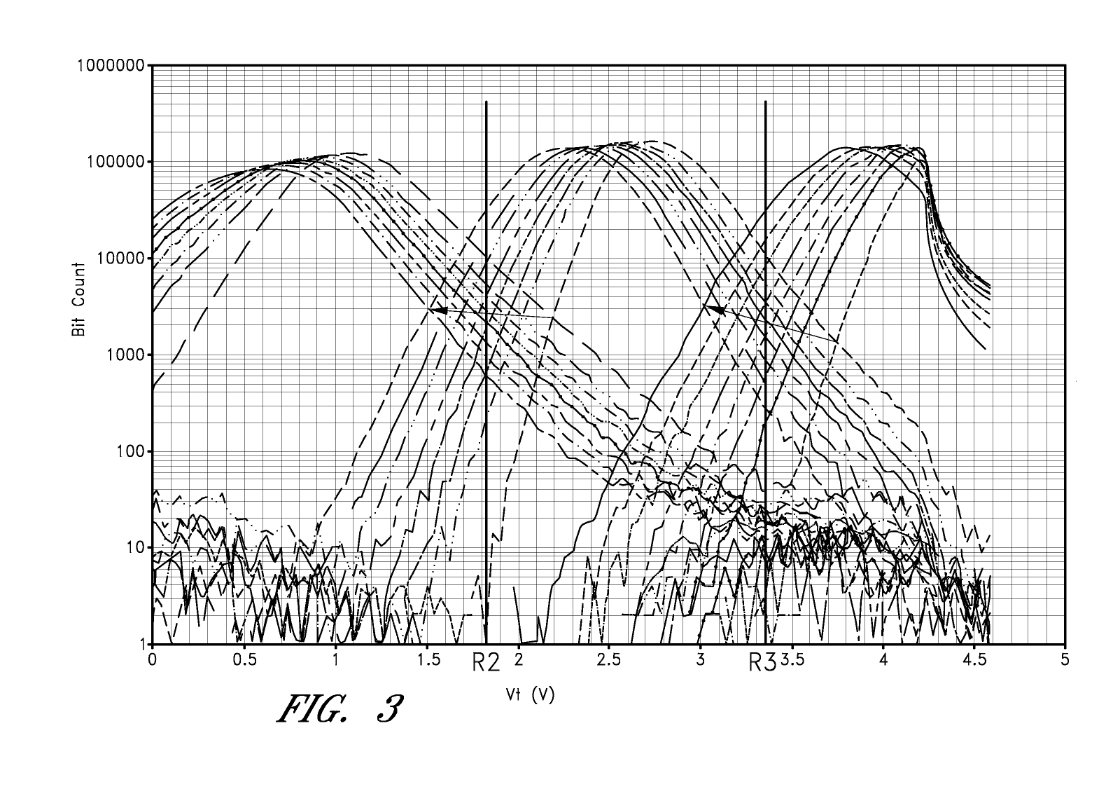

FIG. 3 is a graph showing state cross point shift of a probability distribution according to an embodiment. The graph shows three distribution humps corresponding with three programming states for a solid-state memory. Each distribution is represented by a plurality of curves, each curve corresponding to a different data retention state, with the data retention time generally increasing from right to left. The arrows shown in the graph illustrate the shift in cross points between the respective distributions over time.

The vertical lines labeled ‘R2’ and ‘R3’ along the X-axis represent preset manufacturer's settings for two of the three reading voltages in a two-bit programming scheme. The third reading voltage, R1, may be set relatively closely to 0 V, and is generally ignored in the present discussion for convenience. These preset levels may be set such that initially, they may be disposed to the left of the optimal reading level, wherein over time the optimal reading level moves to the left, passing the preset level. As stated, the arrows indicate how the state cross points may shift with data retention (DR) time (time between initial writing and a current read operation) in an embodiment. To minimize the errors from readout, such reading voltages may be set at or near state cross points. Since the cross points may shift, in certain embodiments, the reading voltages may also shift in order to improve decoding. As illustrated in the graph of FIG. 3, if the reading voltage levels are fixed at the default levels, a significant amount of read errors may result for certain data retention circumstances, such as for memory cells represented by distribution curves at the end of the illustrated arrows.

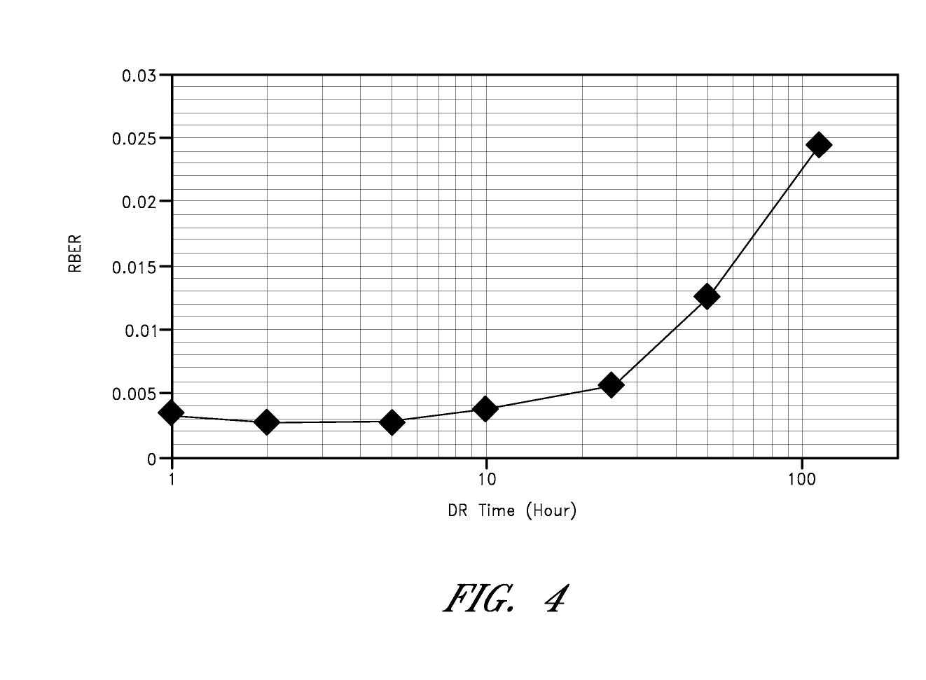

As illustrated in FIG. 3, programming distributions may spread out over time, leading to increases in the bit errors registered during decoding. FIG. 4 is a graph showing bit error rate versus time relationship data in an example solid-state storage device. The graph of FIG. 4 corresponds to a solid-state storage device in which manufacturer default reading voltage levels are used throughout the timeline illustrated in the graph. In the illustrated embodiment, the raw or residual bit error rate (RBER) calculated for the data retention (DR) time=114 hours is approximately 0.0245 in an embodiment. Such an RBER value may represent approximately 10 times the minimum RBER experienced by the device referenced in FIG. 4 (e.g., as shown by the data points taken at about DR time=2 hours and 5 hours, shown on the logarithmic x-axis), where the default VR's may be relatively close to the state cross points.

Even if the readout of a solid-state storage device fails by reading at the manufacturer-provided VR's, the associated data may not necessarily be lost. Many times the data is easily recoverable by shifting the VR's away from the manufacturer's settings to a more optimal voltage level (e.g. the state cross-points shown in FIG. 3). For example, for the case of DR time=114 hours shown in FIG. 4, which has an RBER value of approximately 2.45×10⁻² when read at default VR's, the RBER may be lowered to approximately 2.51×10⁻³ in certain embodiments by adjusting VR's according to the state cross points. That is, in certain embodiments, one order of magnitude improvement in RBER may be obtainable by shifting reading voltage levels. Therefore, reading at adjusted/optimal VR's instead of at the manufacturer's preset default VR's may be desirable to successfully read out written data and suppress RBER. Many applications, such as LLR generation for soft-decision LDPC, may also benefit from information of optimal reading voltages. Various methods and implementations for calculating adjusted/optimal VR's are discussed below.

### Optimal VR Calculation

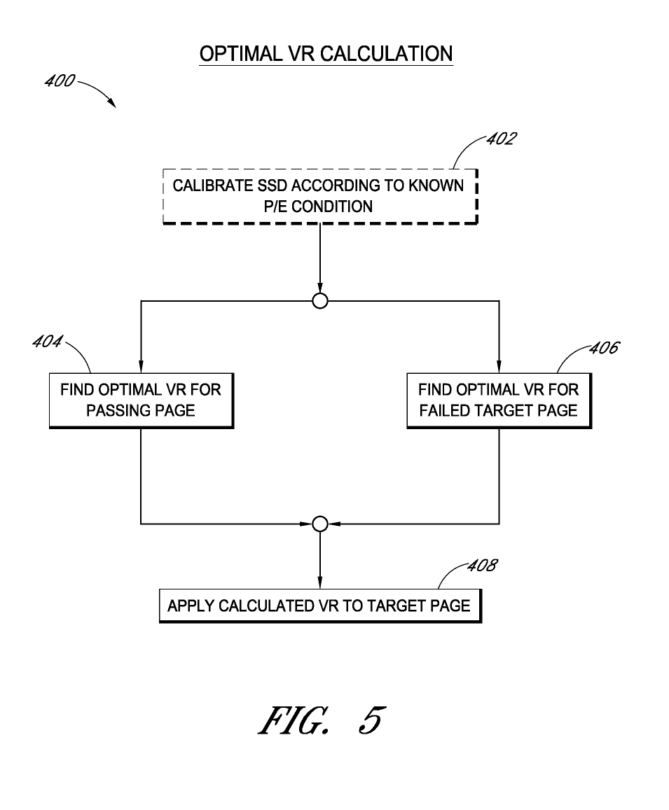

FIG. 5 is a flowchart illustrating in embodiment of a process 400 for calculating reading voltage levels for a solid-state memory. The process 400 may include calibrating the memory based on a known program/erase (P/E) condition (block 402), which may be determined in any desirable manner. In certain embodiments, optimal VR calculation is performed in block 404 with respect to passing reference pages (which may include known data), that provide successful data readout (i.e., bit errors are correctable within the capability of the error correction), and then in block 408 the calculated optimal VR's are applied to target pages associated with the reference pages. In block 406, the process 400 can also perform optimal VR calculation with respect to a failed page, which may be one of the target pages.

In an embodiment, target pages may be associated with one or more reference page(s) having similar characteristics. For example, a passing page in a block may be designated as the reference page for all pages in the same block, since the pages within the same block are assumed to have experienced the same number of P/E cycles. In another example, any passing page within the same block as the target page could be considered a reference page to the target page. In yet another example, any passing page within in a designated range of blocks neighboring the block in which the target page is located may be considered a reference page. On the other hand, in certain embodiments, such as when passing pages are not available, direct finding of optimal VR's on failing pages may also be performed. Certain methods involving direct calculation from failed pages may be more involved than methods requiring use of passing reference pages.

In solid-state storage devices, the P/E cycle number for a given block may be known. Preliminarily calibrating the memory according to its P/E condition may provide data retention information according to P/E cycling, thereby simplifying optimal VR calculation. Three methods for calculating adjusted VR's in solid-state storage devices are disclosed below, including both calibration-based and non-calibration techniques. Furthermore, the methods described below implement VR calculation based on both passing and failing pages. The process 400 may be performed at least in part by the controller 130, the optimal VR calculation module 142, and/or the error correction module 144 described above with respect to FIG. 1.

Data Retention Index Method

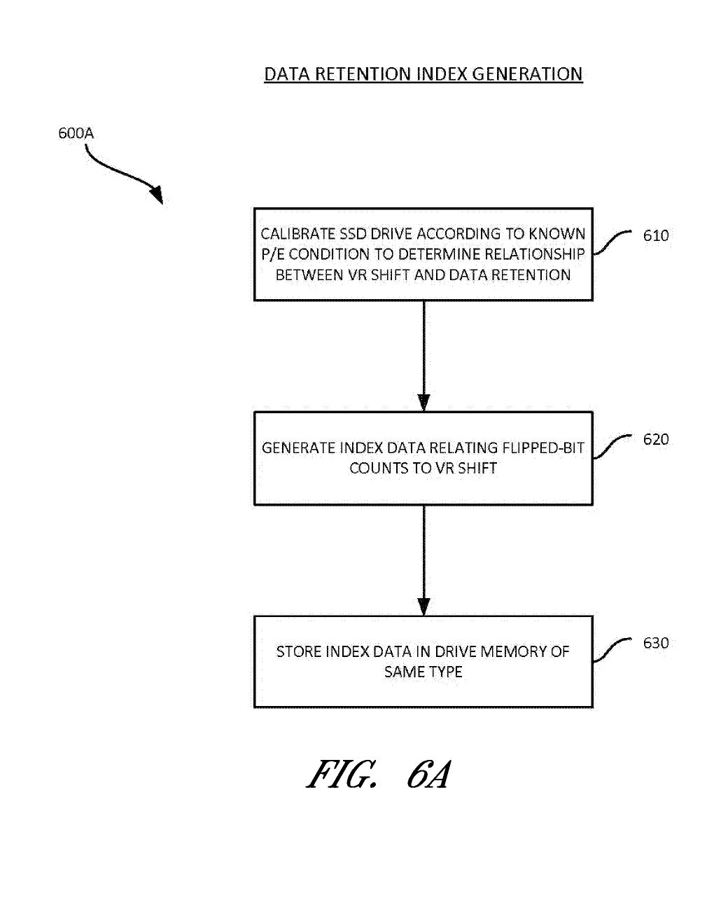

FIG. 6A is a flow diagram illustrating an embodiment of a process 600A for generating a data retention index. This process illustrated in FIG. 6A may be used on passing pages or blocks where the P/E cycle number is known. The process 600A includes, in block 610, calibrating a solid-state storage device according to known P/E condition to determine a relationship between VR shift and data retention. As discussed herein, optimal reading voltage level may depend on various factors such as P/E cycles and date retention history, including time, temperature, etc. Solid-state memory having similar vendor origin and/or technology node may have similar characteristics. Therefore, certain memory blocks that have experienced similar P/E cycles may have similar data retention characteristics; such drives may have similar VR shift when subject to similar storage environments. Preliminary calibration of pages or blocks with known P/E numbers may be implemented to obtain the knowledge of the relation between VR shift and data retention characteristics, since in solid-state storage devices P/E number is often available. In certain embodiments, calibration involves measuring data retention characteristics of a storage device for various P/E conditions. For example, relatively high P/E numbers may be of particular concern since they may represent severe wear, leading to greater probability of read errors. In certain embodiments, calibration involves sampling of a finite set of P/E numbers. Information associated with P/E numbers which are not in the measured set may be estimated using interpolation or extrapolation.

Since data retention time and the other factors can be difficult to obtain, information incorporating all the DR effects can be helpful in estimating optimal VR shift. Once the relationship between VR shift and data retention is known, in block 610 the process 600A generates an index relating flipped-bit counts to optimal voltage shift. Such index data may provide an indication of how and/or to what extent the programming distributions have shifted without the requirement of detailed knowledge of the data storage history, including temperature, time stamp, and the like. Therefore, such index data may be used to adjust reading voltages to minimize the bit error rate in reading. In certain embodiments, the process 600A stores, in block 620, the generated index data in the solid-state storage device, wherein the solid-state storage device may access the index data during normal operation. For example, the index data may be stored in a reserved portion (e.g., reserve table) of the solid-state storage device.

FIG. 6B is a flow diagram illustrating an embodiment of a process 600B for utilizing a data retention index. The process 600B includes determining, in block 640, data retention characteristics of a known reference page, such as flipped-bit count data. The data retention information may be used when accessing, in block 650, data retention index data stored on the drive to look-up adjusted VR levels in block 660. For example, the index may be a look-up table, wherein bit-flip data may be associated with VR shift data in the index. Once VR shift data has been obtained using the index, a target page may be read, in block 670, using the shifted read level, thereby improving data decoding capability. The processes 600A, 600B may be performed at least in part by the controller 130, the optimal VR calculation module 142, and/or the error correction module 144 described above with respect to FIG. 1.

Considering optimal VR shift in response to changing data retention characteristics, error bit count may vary if a solid-state storage device is continually read using manufacturer default VR's as data retention characteristics change. Table A provides an example of error bit count information vs. data retention condition, where fluctuating data retention condition is based on elapsed time, when reading at the default VR for R2 for a block of an embodiment of a solid-state storage device:

TABLE A

| DR time (at 40° C.) | 1 −> 0 | log(1 −> 0) | R2 |
|---|---|---|---|
| 0 hr | 174084 | 5.240759 | 2.28 |
| 1 day | 98952 | 4.995425 | 2.1 |
| 2 days | 85064 | 4.929746 | 2.06 |
| 1 week | 58364 | 4.766145 | 1.94 |
| 1 month | 38728 | 4.588025 | 1.8 |
| 3 months | 27430 | 4.438226 | 1.68 |
| 6 months | 21518 | 4.332802 | 1.6 |
| 1 year | 16886 | 4.227527 | 1.52 |
| 2 years | 13529 | 4.131266 | 1.46 |

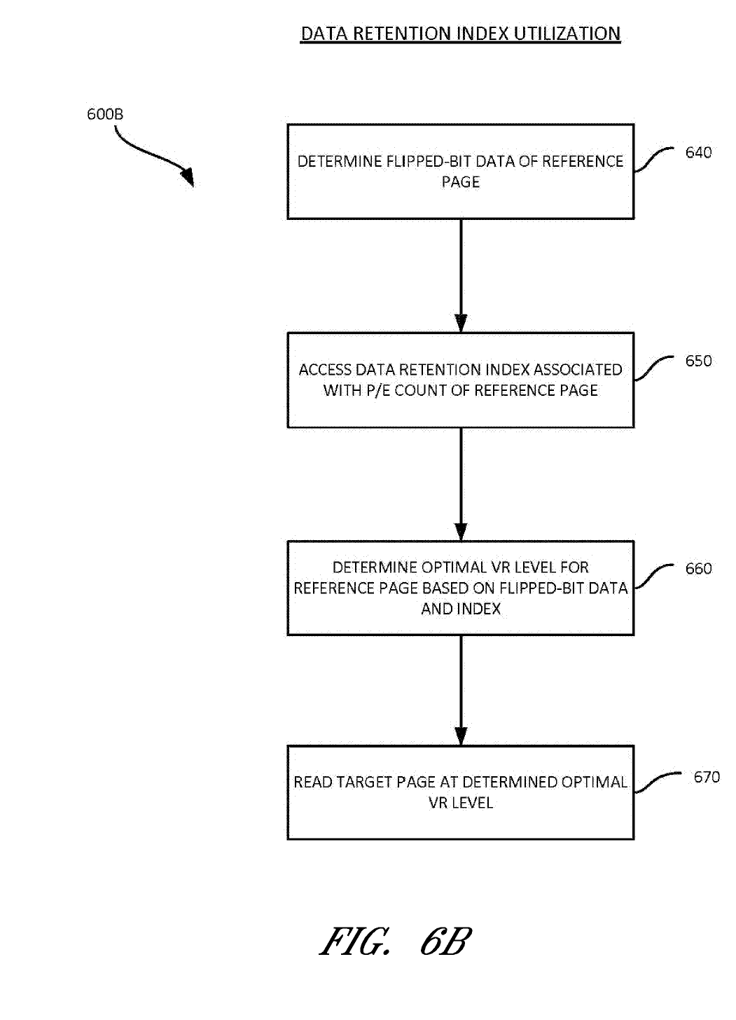

The third column of Table A includes data representing the logarithmic value of the lower page 1->0 flip bit counts. FIG. 7 is a graph showing reading voltage level shift versus bit error count relationship data in an embodiment. As shown in the graph of FIG. 7, VR shift may have a linear relationship with the log of flipped bit count data in certain embodiments.

Data retention calibration may provide certain information associated with VR shift. For example, Table B provides R2 and R3 shift data charted over stimulated changing data retention conditions (increasing age of the solid-state storage device stimulated through baking the memory at a certain temperature for the various periods of time as shown in Table B). The voltage shift values illustrated in Table B are determined with respect to default values (or manufacturer settings) of R2=1.82 V and R3=3.36 V.

TABLE B

| Bake Hour | Optimal R2 | Optimal R3 | R2 shift | R3 shift |
|---|---|---|---|---|
| 0 | 2.19 | 3.74 | 0.37 | 0.38 |
| 1 | 2.02 | 3.56 | 0.2 | 0.2 |
| 2 | 1.93 | 3.46 | 0.11 | 0.1 |
| 5 | 1.85 | 3.38 | 0.03 | 0.02 |
| 10 | 1.78 | 3.3 | −0.04 | −0.06 |
| 25 | 1.68 | 3.2 | −0.14 | −0.16 |
| 50 | 1.61 | 3.12 | −0.21 | −0.24 |
| 114 | 1.5 | 3.02 | −0.32 | −0.34 |

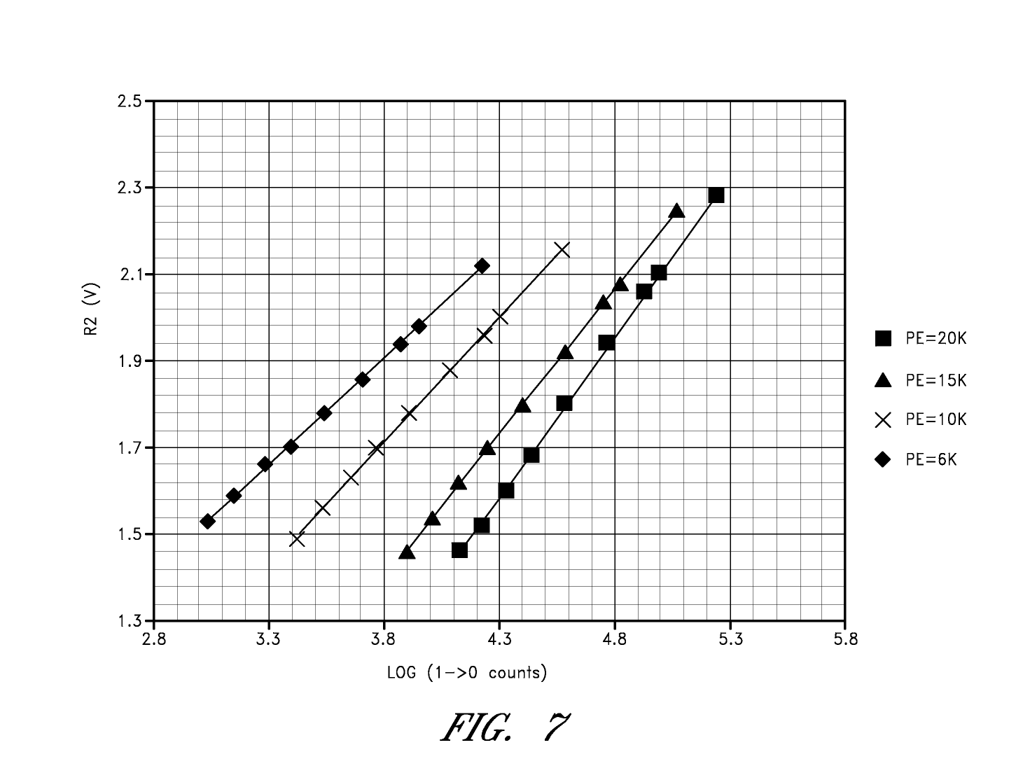

FIG. 8 is a graph showing the reading voltage level shift data for both R2 and R3 contained in Table B in an embodiment. The graph of FIG. 8 shows that for certain embodiments, a substantially linear relationship may exist between R2 shift and R3 shift. Therefore, it may be possible to derive voltage shift for one of R2 or R3 based at least in part on knowledge of the other. If there exists a relation between R2 and R3 shifts, lower page information may be used to predict upper page behavior. In certain embodiments, utilization of such relationship information may help save system resources.

RBER Polynomial Fitting Method

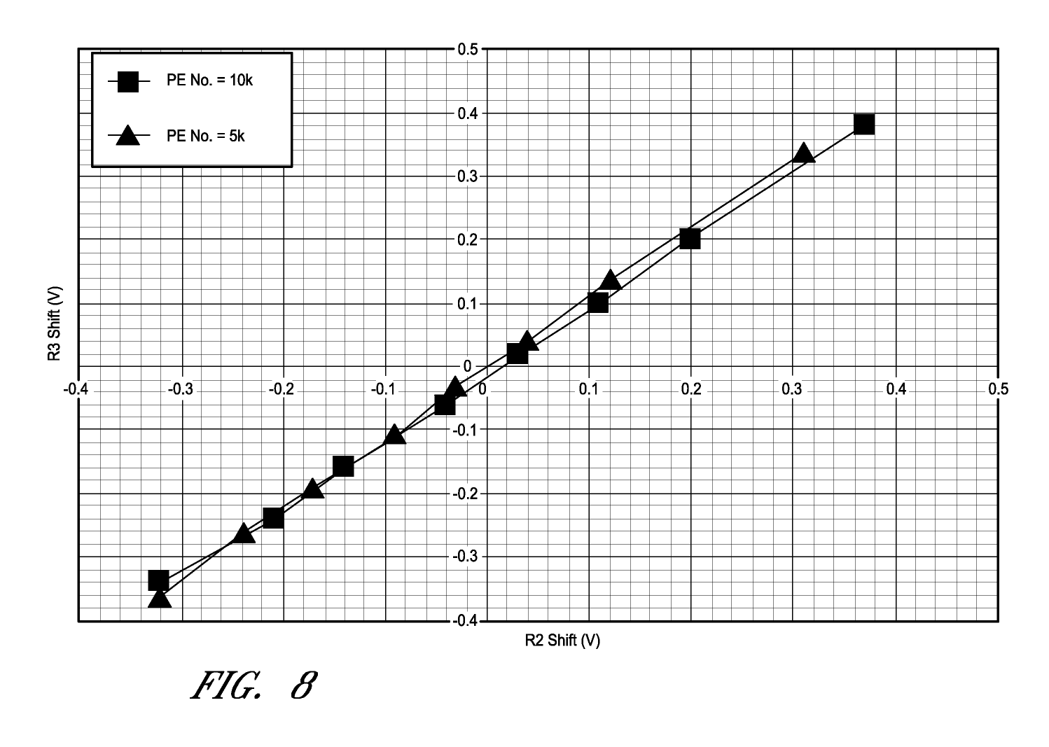

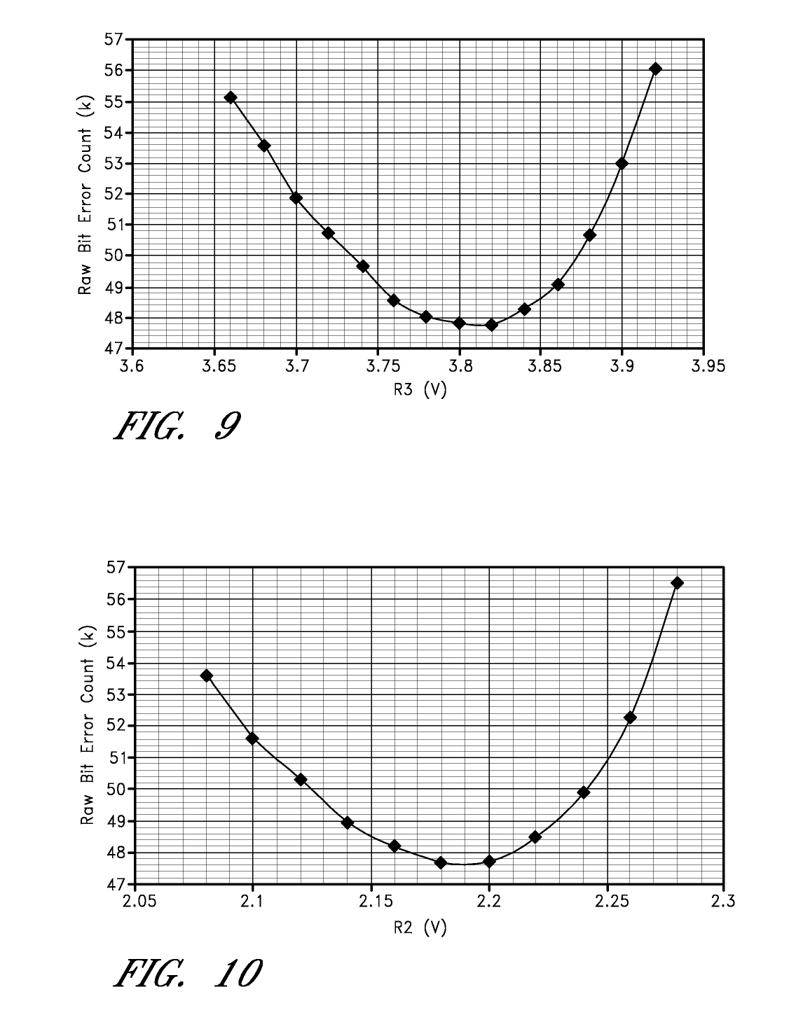

Certain embodiments disclosed herein provide methods for calculating VR shift using polynomial fitting techniques. In an embodiment, VR shift may be calculated using polynomial fitting for passing reference pages or blocks. Knowledge of P/E cycle condition may not be required. FIGS. 9-10 may be helpful in illustrating how polynomial fitting of raw bit error rate count data may be used to calculate VR shift. FIGS. 9-10 show graphical bit error count data for one or more embodiments of solid-state storage devices, where the raw bit error counts are shown resulting from scanning one VR with the other VR fixed in an MLC scheme. As shown in the figures, in certain embodiments, raw bit error count data can be approximately fitted by a polynomial function, such as a parabola. Therefore, modeling the bit error rate data can allow for generation of a mathematical representation of the bit error rate over the range of VR's, which may be solved to determine a point of lowest bit error count. For example, the derivative of a second-order polynomial (i.e., parabolic) equation can be solved for to find a zero-slope point of the curve, which may correspond to a bit error low point. In the example of FIG. 9, the lowest bit error is found at approximately 3.82 V for the R3 level, and in the example of FIG. 10, the bit lowest error is found at approximately 2.18 V for the R2 level.

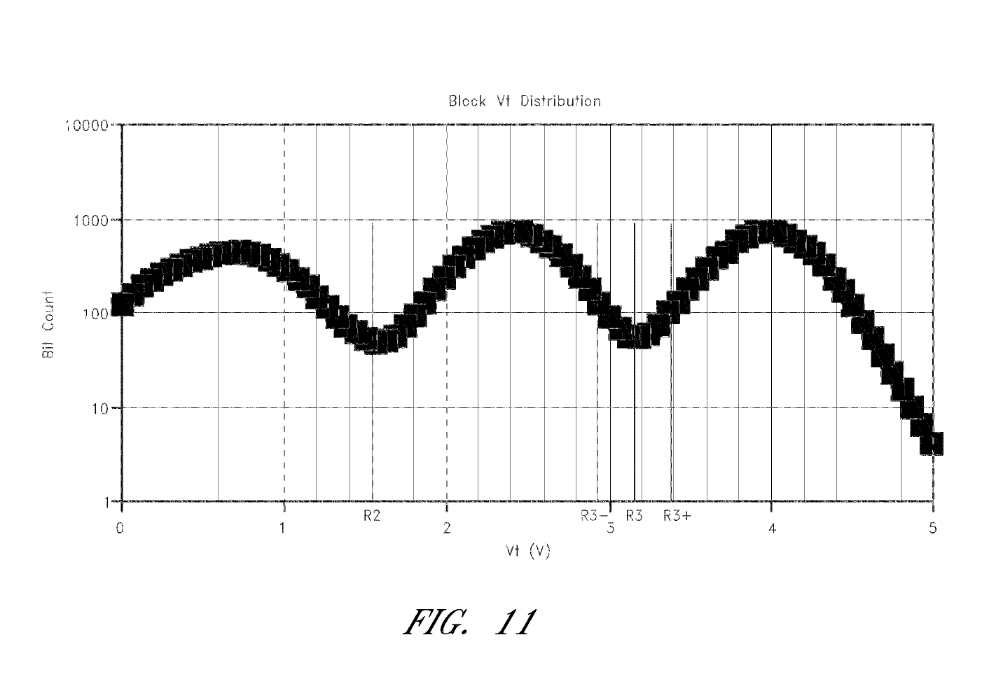

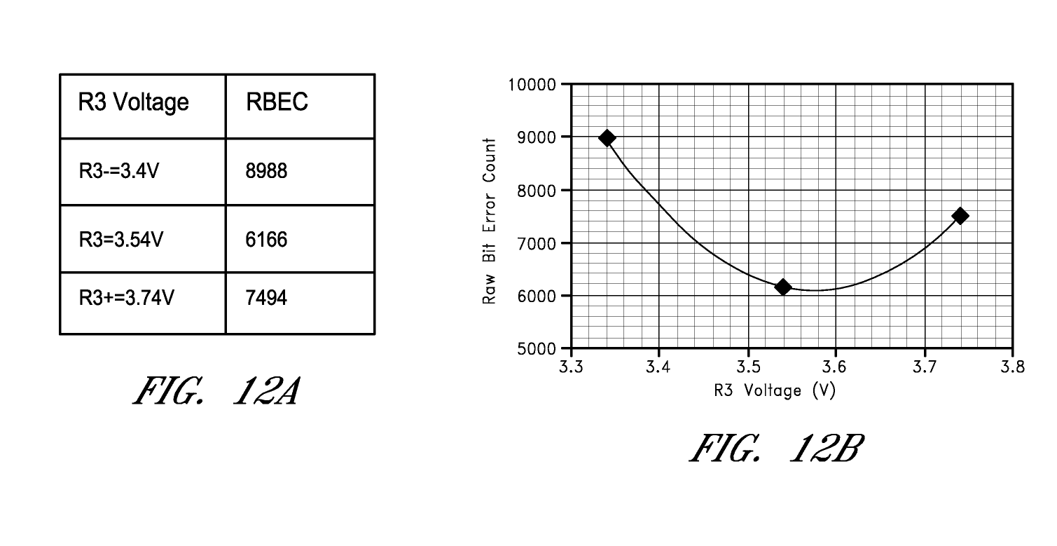

FIG. 11 is a graph showing bit error count data in an embodiment. In certain embodiments, three or more bit error count data points are determined over a range of reading voltage levels for a reference page or block. For an MLC scheme, one VR (R2) may be fixed, while a second VR (R3) is shifted to obtain the multiple data points. For example, as shown in the graph of FIG. 11, R3 may be shifted by approximately 0.2 V between reads. The three or more reads may all be taken within a predetermined range of a manufacturer's default read level. In certain embodiments, raw bit error count is plotted vs. voltage and parabolic fitting is used to fit the three or more data points to a third-order curve. In the embodiment of FIG. 11, the optimal reading voltage level R3 may be approximately 3.13 V, as shown, which may be determined by solving for the point where the derivative of the third-order curve is equal to zero. In may be necessary for at least one data point to be on each side of the local minima in order to properly fit the curve. FIGS. 12A-B provide a table of bit error data and graphical representation of a third-order polynomial fit to the data at around R3, respectively.

Shown in Table C are optimal VR's found using polynomial fitting and raw bit error count improvement data over a range of P/E cycle counts for a block of memory in an embodiment. As shown, adjusting VR using parabolic fitting may provide bit error reduction by a factor of three or more for P/E numbers larger than 1 k in certain embodiments. In Table C below, the rows labeled R1(V), R2(V), and R3(V) indicate the VR's used in the optimal reads at the individual P/E levels.

TABLE C

| | P/E No. (′000s) | | | | | | | | |
|---|---|---|---|---|---|---|---|---|---|
| | 0 | 1 | 2 | 3 | 4 | 5 | 6 | 7 | 8 |
| R1 (V) | 0.18 | 0.18 | 0.18 | 0.18 | 0.18 | 0.18 | 0.18 | 0.18 | 0.18 |
| R2 (V) | 1.88 | 2.02 | 1.94 | 2.00 | 2.02 | 2.06 | 2.06 | 2.08 | 2.12 |
| R3 (V) | 3.40 | 3.54 | 3.56 | 3.60 | 3.62 | 3.66 | 3.64 | 3.66 | 3.70 |
| Raw Bit | 153 | 6493 | 19593 | 37349 | 59511 | 87853 | 117851 | 147123 | 182587 |
| Error Count | | | | | | | | | |
| (default) | | | | | | | | | |
| Raw Bit | 151 | 2137 | 5930 | 10025 | 15802 | 22708 | 31922 | 40237 | 50762 |
| Error Count | | | | | | | | | |
| (optimal) | | | | | | | | | |
| Improvement | 1.01 | 3.04 | 3.30 | 3.73 | 3.77 | 3.87 | 3.69 | 3.66 | 3.60 |
| factor | | | | | | | | | |

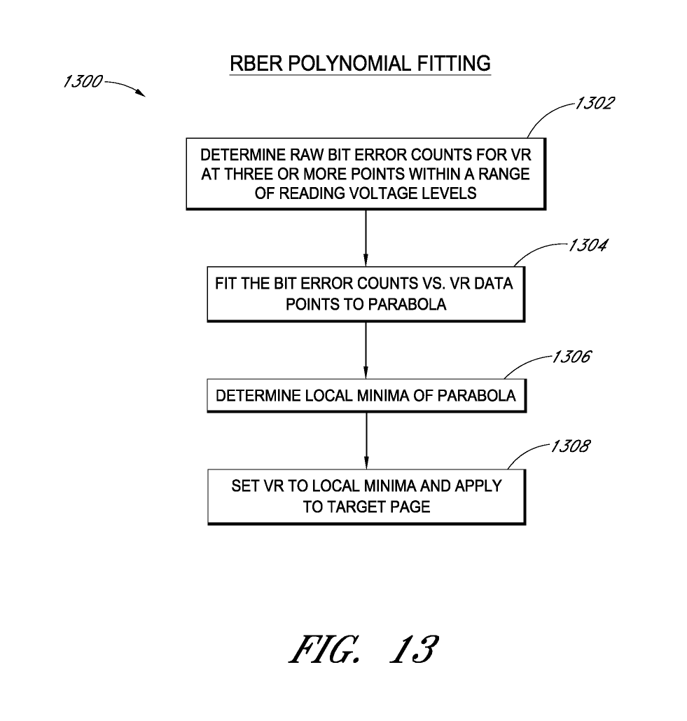

FIG. 13 is a flow diagram illustrating an embodiment of a process 1300 for calculating reading voltage levels using the polynomial fitting method described above. The process 1300 includes determine raw bit error counts for VR at three or more points within a range of read voltage levels (block 1302). The process 1300 further includes fitting the bit error count versus RV data points to a parabola (block 1304). Once a parabolic equation has been generated to fit the bit error data, the equation is solved to determine a local minima of parabola, such as by setting the derivative of the function to zero and solving to find the corresponding VR value (block 1306). One or more target pages may subsequently be decoded using the solved-for VR value, thereby improving decoding results (block 1308). The process 1300 may be performed at least in part by the controller 130, the optimal VR calculation module 142, and/or the error correction module 144 described above with respect to FIG. 1.

Cumulative Distribution Polynomial Fitting Method

The two methods of optimal VR calculation discussed above work for passing blocks or pages, where the ECC decoding successfully decodes data from the blocks or pages. Sometimes the internal voltage levels of failing pages or blocks may vary substantially from those of passing pages or blocks, such that applying adjusted reading voltage levels obtained from the passing pages is insufficient for adequately recovering the data in such failing pages/blocks. Therefore, being able to find optimal VR's directly from a failing target page may be desirable in certain situations, for example, when adjusted VR's calculated from one of the above methods do not sufficiently reduce the number of error bits so that the error correction can recover data from a target page. Certain embodiments disclosed herein provide for optimal VR calculation from failing pages using cumulative bit count distribution information.

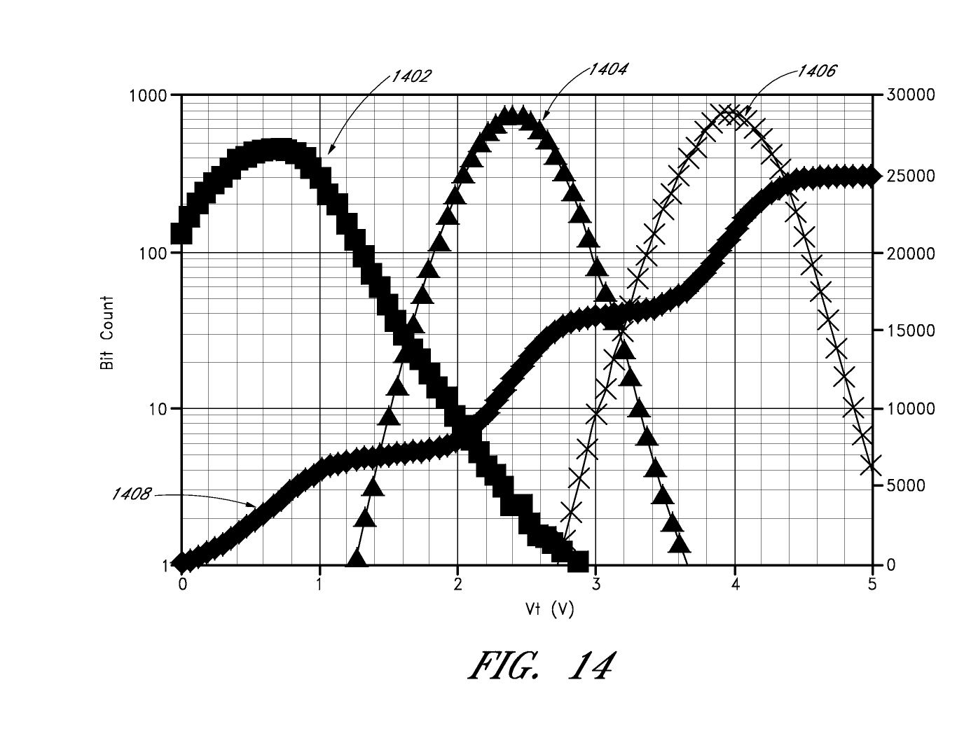

FIG. 14 is a graph showing cumulative state distribution information for an embodiment of a solid-state device. The distribution graph shows distributions for three programming states (curves 1402, 1404, and 1406). The graph further shows a curve representing the cumulative number of cells having a voltage charge level at or lower than the relevant voltage point on the x-axis. In further detail, the discrete state distributions of FIG. 14 are shown by three distinctive peak curves. The curve 1408 (comprising diamond-shaped data points and traversing the entire illustrated voltage domain) may represent the count of bits having the value ‘1’ when R2 shifts from left to right (there may be a constant attached to the data that is omitted in the curve for simplicity), and is called the cumulative distribution. As shown, the steepest slopes for the cumulative distribution curve 1408 correspond to the three peaks where the count of bits having the value ‘1’ increases at the fastest rate. In each peak, the left side of the peak is associated with the value ‘1’ for that programming state. The flattest slopes for the curve may correspond to the overlap regions between the states. Because the optimal VR's are typically found in these overlap regions, an embodiment determines the optimal VR's by obtaining a cumulative distribution curve such as curve 1408 and determining locations of the flattest slopes on the cumulative distribution curve. Such a process is further described below.

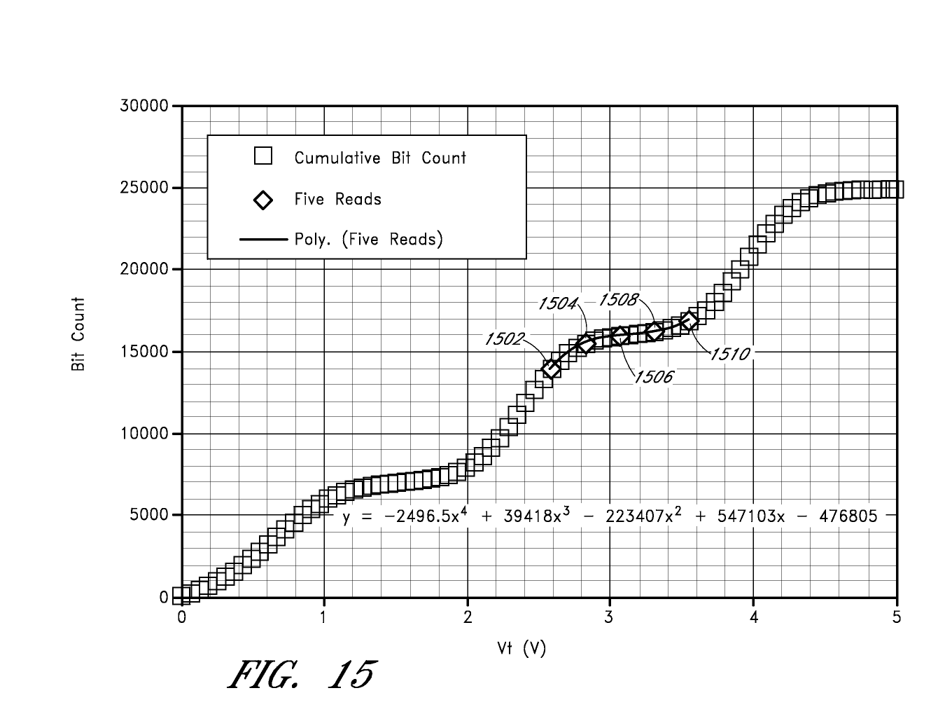

FIG. 15 is a graph showing cumulative state distribution information in an embodiment. The illustrated curve may correspond to the cumulative distribution curve 1408 shown in FIG. 14. In certain embodiment, four or more bit count data points are determined for the cumulative distribution, as shown (five reads 1502, 1504, 1506, 1508, and 1510 at different voltage levels are shown in the example of FIG. 15). For example, the bit count reads may be performed within a predetermined range of a manufacturer default VR. The four or more reads may be taken over a range assumed or known to contain an overlap region between two programming states. The four or more data points generated may be fitted to a third-order or higher-order polynomial. As shown in the embodiment of FIG. 15, the five reads are fitted to a fourth-order polynomial having the following equation:

y(x)=−2496.5x⁴+39418x³−223407x²+547103x−476805 (1)

In certain embodiments, the point at which the fitted polynomial (which may correspond to the cumulative distribution curve shown in FIG. 14) has the least slope over a range of interest may be used to estimate the optimal reading voltage for a respective programming interval.

The point of the function having the flattest slope over the range of data points may be determined by solving the equation y″(x)=0 for the variable ‘x,’ representing the to be determined optimal VR. For example, solving y″(x)=0 may yield an optimal VR value of approximately 3.13 V. By comparison to the corresponding state cross point shown in FIG. 14, it is apparent that this value is near to the state cross point of the two distributions on the right side of the graph. While discussion of cumulative distribution curve-fitting techniques herein focuses on VR values between third and fourth programming state distributions in an MLC scheme, the principles disclosed may be applicable to other overlap regions as well.

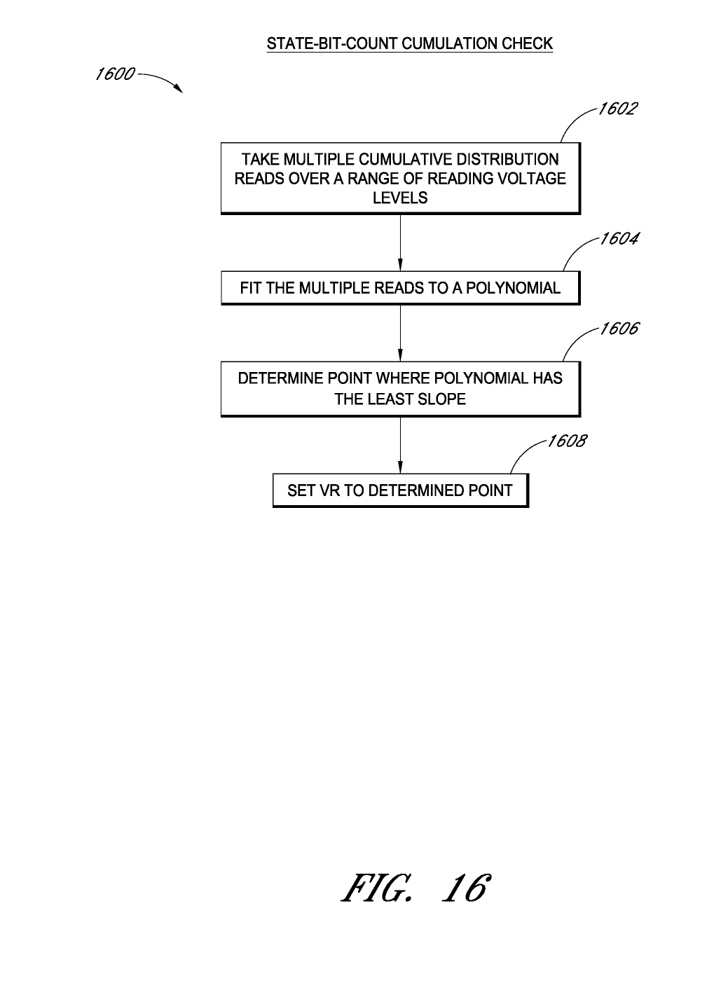

FIG. 16 is a flow diagram illustrating an embodiment of a process 1600 for calculating reading voltage read using polynomial fitting. The process 1600 involves taking multiple cumulative distribution reads over a range of reading voltage read in block 1602 and fitting the multiple reads to a polynomial in block 1604. For example, four or more reads may be taken to provide data for a third-order fourth-order, or higher-order polynomial. At block 1606, the process 1600 involves determining a point where the polynomial has the least slope within a range of voltage values. The reading voltage level may then be set to the determined least-sloped point and used to decode the page in block 1608. The process 1600 of FIG. 16 may advantageously provide for direct calculation of optimal VR level from a failing page. Therefore, the process 1600 may be suitable or desirable for where it is difficult to find a passing page or a passing page with similar characteristics. The process 1600 may be performed at least in part by the controller 130, the optimal VR calculation module 142 and/or the error correction module 144 described above with respect to FIG. 1.

### Alternative Embodiments

The read levels, states, and coding schemes associated with voltage level distributions described herein, as well as variables and designations used to represent the same, are used for convenience only. As used in this application, “non-volatile solid-state memory” typically refers to solid-state memory such as, but not limited to, NAND flash. However, the systems and methods of this disclosure may also be useful in more conventional hard drives and hybrid hard drives including both solid-state and hard drive components. The solid-state storage devices (e.g., dies) may be physically divided into planes, blocks, pages, and sectors, as is known in the art. Other forms of storage (e.g., battery backed-up volatile DRAM or SRAM devices, magnetic disk drives, etc.) may additionally or alternatively be used.

Those skilled in the art will appreciate that in some embodiments, other types of data storage devices and/or data retention monitoring can be implemented. In addition, the actual steps taken in the processes shown in FIGS. 5, 6A, 6B, 13, and 16 may differ from those shown in the figures. Depending on the embodiment, certain of the steps described above may be removed, others may be added.

While certain embodiments have been described, these embodiments have been presented by way of example only, and are not intended to limit the scope of protection. Indeed, the novel methods and systems described herein may be embodied in a variety of other forms. Furthermore, various omissions, substitutions and changes in the form of the methods and systems described herein may be made. The accompanying claims and their equivalents are intended to cover such forms or modifications as would fall within the scope and spirit of the protection. For example, the various components illustrated in the figures may be implemented as software and/or firmware on a processor, ASIC/FPGA, or dedicated hardware. Also, the features and attributes of the specific embodiments disclosed above may be combined in different ways to form additional embodiments, all of which fall within the scope of the present disclosure. Although the present disclosure provides certain preferred embodiments and applications, other embodiments that are apparent to those of ordinary skill in the art, including embodiments which do not provide all of the features and advantages set forth herein, are also within the scope of this disclosure. Accordingly, the scope of the present disclosure is intended to be defined only by reference to the appended claims.

What is claimed is:

1. A method of calibrating one or more solid-state storage devices, the method comprising:
determining a relationship between reading voltage level shift and flipped-bit count for a first solid-state drive having known program/erase cycle count characteristics;
generating index data relating flipped-bit count to reading voltage level shift based at least in part on the determined relationship; and
storing the index data in memory of the first solid-state drive or at least a second solid-state drive.

2. The method of claim 1, wherein the relationship is a substantially linear relationship between log values of the flipped-bit counts and reading voltage level.

3. The method of claim 1, wherein determining the relationship between reading voltage level shift and flipped-bit count comprises subjecting the first solid-state drive to a range of temperature conditions.

4. The method of claim 1, wherein determining the relationship between reading voltage level shift and flipped-bit count comprises calculating flipped-bit counts at discrete time periods corresponding to various stages of aging of the first solid-state drive.

5. The method of claim 1, wherein determining the relationship between reading voltage level shift and flipped-bit count comprises reading one or more pages of memory of the first solid-state drive under varying data retention conditions using a default reading voltage level.

6. A solid-state storage device comprising:
a non-volatile solid-state memory array comprising a plurality of non-volatile memory devices configured to store data; and
a controller configured to determine optimal reading voltage levels for memory cells of the plurality of non-volatile memory devices by at least:
determining flipped bit count data associated with a reference bit stream of the memory array;
accessing index data stored in the solid-state storage device relating flipped-bit count to shift in reading voltage level;
determining an adjusted reading voltage level based at least in part on the flipped-bit count data associated with the reference bit stream and the index data; and
reading a target bit stream of the memory array using the adjusted reading voltage level.

7. The solid-state storage device of claim 1, wherein the reference bit stream has program/erase (P/E) cycle characteristics associated with the index data.

8. The solid-state storage device of claim 1, wherein the controller is further configured to decode a lower page encoded by memory cells associated with the target bit stream using the adjusted reading voltage level and decode an upper page encoded by the memory cells based at least in part on a determined relationship between lower page reading voltage levels and upper page reading voltage levels.

9. The solid-state storage device of claim 1, wherein the index comprises a look-up table.

10. A solid-state storage device comprising:
a non-volatile solid-state memory array comprising a plurality of non-volatile memory devices configured to store data; and
a controller configured to determine optimal reading voltage levels for the plurality of non-volatile memory devices by at least:
determining bit error counts associated with each of three or more reads of a reference page, including reads at first, second, and third reading voltage levels;
fitting the bit error counts associated with the first, second, and third reading voltage levels to a parabolic function of bit error count versus reading voltage level;
calculating a local minima of the parabolic function; and
reading a target page at an adjusted reading voltage level associated with the local minima of the parabolic function.

11. The solid-state storage device of claim 9, wherein the first, second, and third reading voltage levels are within a predetermined range of a default reading voltage level.

12. The solid-state storage device of claim 9, wherein the controller is further configured to:
if a lower page is needed, decode a lower page of a memory cell associated with the target page using the adjusted reading voltage level; and
if an upper page is needed, decode the memory cell based at least in part on a determined relationship between lower page reading voltage levels and upper page reading voltage levels.

13. The solid-state storage device of claim 11, wherein the relationship between lower page reading voltage levels and upper page reading voltage levels is substantially linear.

14. The solid-state storage device of claim 9, wherein the controller is configured to determine the bit error counts using a fixed lower page reading voltage read in combination with each of the three or more reads of the reference page.

15. The solid-state storage device of claim 9, wherein reading the target page at the adjusted reading voltage level reduces bit error counts by a factor of 3 or greater compared to reading the target page at the default reading voltage level, wherein the target page has a P/E cycle count greater than 1,000.

16. A solid-state storage device comprising:
a non-volatile solid-state memory array comprising a plurality of non-volatile memory devices configured to store data; and
a controller configured to determine optimal reading voltage levels for the plurality of non-volatile memory devices by at least:
determining cumulative ‘1’ or ‘0’ counts associated with each of four or more reads of a page at different reading voltage levels;
fitting the cumulative ‘1’ or ‘0’ counts to a third-order or higher polynomial function of cumulative bit count versus voltage level;
determining an adjusted reading voltage level associated with a point of the polynomial function having a lowest slope value over a range of voltages; and
reading the page at the adjusted reading voltage level.

17. The solid-state storage device of claim 16, wherein the controller is further configured to determine the adjusted reading voltage level without reference to known reference data values or P/E cycle information.

18. The solid-state storage device of claim 16, wherein the four or more reads at different reading voltage levels are within a predetermined range of a default reading voltage level.

19. The solid-state storage device of claim 18, wherein the predetermined range is within 500 mV of the default reading voltage level.

20. The solid-state storage device of claim 16, wherein the controller is further configured to:
if a lower page is needed, decode a lower page of a memory cell associated with the page using the adjusted reading voltage level; and
if an upper page is needed, decode the memory cell based at least in part on a determined relationship between lower page reading voltage levels and upper page reading voltage levels.

21. The solid-state storage device of claim 16, wherein determining the adjusted reading voltage level comprises calculating an inflection point of the polynomial function.

22. The solid-state storage device of claim 16, wherein determining the adjusted reading voltage level comprises calculating a voltage level associated with a second order derivative of the polynomial function equal to zero.

23. The solid-state storage device of claim 16, wherein the adjusted reading voltage level is associated with a lower page read, and wherein the controller is further configured to determine one or more additional adjusted reading voltage levels associated with an upper page read and read the page at the one or more additional adjusted reading voltage levels.
